(19) United States
(12) Patent Application Publication
(10) Pub. No.: US 2022/0197524 A1
(43) Pub. Date: Jun. 23, 2022

(54) WORKLOAD BASED TUNING OF MEMORY TIMING PARAMETERS

(71) Applicant: ADVANCED MICRO DEVICES, INC., Santa Clara, CA (US)

(72) Inventors: Max RUTTENBERG, Bellevue, WA (US); Vedula Venkata Srikant BHARADWAJ, Bellevue, WA (US); Yasuko ECKERT, Bellevue, WA (US); Mark H. OSKIN, Bellevue, WA (US); Anthony GUTIERREZ, Bellevue, WA (US)

(21) Appl. No.: 17/128,844

(22) Filed: Dec. 21, 2020

(51) Int. Cl. G06F 3/06

(52) U.S. Cl. CPC G06F 3/0634; G06F 3/0673; G06F 3/0604

(57) ABSTRACT

A processor sets memory timing parameters based on a profile of a workload to be executed at the processor and based on a thermal budget associated with the processor. For a given workload and amount of available thermal headroom, as indicated by a detected temperature, the processor adjusts one or more of the memory timing parameters according to the workload profile. The processor is thereby able to tailor the memory timing parameters according to the memory access behavior of the workload, improving overall processing efficiency.

### BACKGROUND

To improve overall processing efficiency, modern processing systems typically employ multichannel high bandwidth memory, such as multichannel dynamic random-access memory (DRAM). The DRAM modules have a strict a power budget required for reliable operation. As industry pushes towards the manufacturing of exascale systems, there is a need to keep these power budgets low while maintaining DRAM data density and improving DRAM bandwidth. However, technology scaling is yielding decreased marginal gains due to the lack of static power scaling. One way to achieve a low power budget is to modify the underlying architecture of the DRAM modules to support lower power consumption. However, these modifications can sacrifice DRAM density, and DRAM modules with these modifications can be difficult and expensive to manufacture.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a processing system that adjusts memory timing parameters based on a profile of a workload to be executed in accordance with some embodiments.

FIG. 2 is a diagram illustrating an example of the processing system of FIG. 1 adjusting memory timing parameters based on a workload profile in accordance with some embodiments.

FIG. 3 is a diagram illustrating an example set of adjustments of memory timing parameters for the processing system of FIG. 1 in accordance with some embodiments.

FIG. 4 is a diagram illustrating an example set of factors for profiling a workload of the processing system of FIG. 1 in accordance with some embodiments.

FIG. 5 is a flow diagram of a method of adjusting memory timing parameters at a processing system based on a workload profile in accordance with some embodiments.

### DETAILED DESCRIPTION

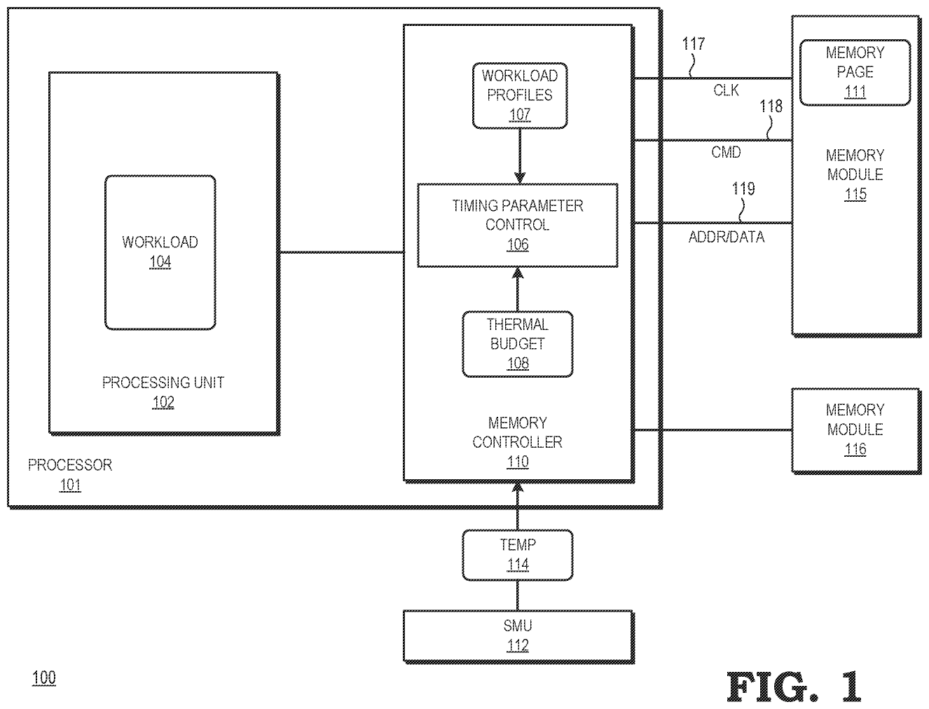

FIGS. 1-5 illustrate techniques for setting memory timing parameters based on a profile of a workload to be executed at a processor and based on a thermal budget associated with the processor. For a given workload and amount of available thermal headroom, as indicated by a detected temperature, the processor adjusts one or more of the memory timing parameters according to the workload profile. The processor is thereby able to tailor the memory timing parameters according to the memory access behavior of the workload, improving overall processing efficiency. Furthermore, in some embodiments the processor employs existing protocols to adjust the memory timing parameters, so that the processing efficiency is improved without requiring redesign of the memory modules themselves.

To illustrate further, in some embodiments a processing system employs DRAM modules that have adjustable timing parameters, such as memory clock frequency, command delay parameters (e.g., Row Column Delay (RCD) parameters), and the like. Conventionally, a processor of the processing system sets the timing parameters to comply with specifications set by, for example, a vendor of the DRAM modules. However, the vendor often sets the specifications for the timing parameters conservatively and based on a maximum expected temperature that may not hold for the actual operating conditions of the processor. Furthermore, in many cases different workloads to be executed at the processor have different memory access behavior and can therefore benefit from different adjustments in memory timing parameters. For example, some workloads generate a relatively high memory traffic rate with a low amount of page locality (i.e., a low page hit rate at the memory). Such workloads benefit from setting the memory timing parameters to result in relatively faster loading of pages at the memory. In contrast, other workloads generate a relatively high memory traffic rate with a high amount of page locality (i.e., a high page hit rate at the memory). Such workloads benefit from setting the memory timing parameters that result in rapid input/output at the memory module (e.g., timing parameters that result in the input and output busses of the memory receiving and providing data relatively quickly). Using the techniques described herein, a processor identifies the expected memory access behavior of each workload and sets the memory timing parameters based on the expected memory access behavior, thereby tailoring the timing characteristics of the DRAM modules according to the expected behavior and improving overall performance of the processing system.

In some embodiments, to set the timing parameters for a DRAM module, the processor determines the workload to be executed. In different embodiments, the processor identifies the workload at different levels of granularity. For example, in some embodiments, each workload corresponds to a different software application, and the processor identifies the workload based on an application identifier generated by the application itself. In other embodiments, an application to be executed at the processor has different phases, with each phase exhibiting different memory access behavior, and the workloads identified by the processor correspond to the different application phases. In some embodiments, the processor identifies the workload associated with a given phase by monitoring the memory access behavior of the application and dynamically changing the identified workload based on the memory access behavior. For example, in some embodiments the processor identifies the workload based on a memory traffic rate, a number of memory accesses (reads, writes, or both), memory access sizes, memory page hits, misses, or conflicts, a spatial locality of memory accesses, and the like, or any combination thereof.

In response to identifying the workload to be executed, a memory controller of the processor identifies a thermal headroom for the processor. For example, in some embodiments the memory controller identifies a detected temperature for the processor and compares the detected temperature to a thermal budget for the processor to determine the amount of thermal headroom. The memory controller accesses a set of workload profiles that indicate, for each combination of workload and temperature, a corresponding set of memory timing parameter values. The memory controller then sends one or more commands to one or more of the processing system memory modules to set the memory timing parameters to the indicated values. In some cases, the memory controller changes the memory timing parameters by adjusting one or more voltages of memory signaling applied to the memory module.

In different embodiments, the workload profiles employed by the memory controller are generated in different ways. For example, in some embodiments, the workload profile for an application is determined during compilation of the application by using statistical analysis techniques or by running a sample on a real processor. The workload profile information is then stored in metadata of the compiled binary. In different embodiments, the metadata in the binary is retrieved in different ways, such as by an operating system or other program extracting the metadata during application runtime, via one or more specified instructions that set the workload profile based on the metadata, by using memory-mapped I/O (MMIO) to inform the memory controller of the workload profile, or by firmware employing a control loop to generate the workload profile based on the metadata.

In other embodiments, the workload profile is generated via software profiling at runtime. For example, in some embodiments an operating system or other program, or the application itself, employs performance profiling tools to determine the memory access behavior of the application. These performance profiling tools monitor memory accesses generated by the program and the behavior of the memory modules in response to the accesses, and based on the monitoring the tools collect statistical information representative of the memory access behavior of the application, such as memory traffic rate, a number of memory accesses (reads, writes, or both), memory access sizes, memory page hits, misses, or conflicts, a spatial locality of memory accesses, and the like. The performance profiling tools apply the statistical information to a specified workload profile model to generate the workload profile for the application. In other embodiments, the runtime profiling and workload profile generation is performed at least in part by dedicated hardware of the processor. In still other embodiments, the runtime profiling and workload profile generation is performed at least in part by firmware executing at the processor.

FIG. 1 illustrates a processing system 100 that adjusts memory timing parameters based on a profile of a workload to be executed in accordance with some embodiments. The processing system 100 is generally configured to execute sets of instructions (e.g., applications) that, when executed, manipulate one or more aspects of an electronic device in order to carry out tasks specified by the sets of instructions. Accordingly, in different embodiments the processing system 100 is part of one of a variety of electronic devices, such as a desktop computer, laptop computer, server, smartphone, tablet, game console, and the like.

To facilitate execution of the sets of instructions, the processing system 100 includes a processor 101, a plurality of memory modules (e.g., memory modules 115, 116), and a system management unit (SMU) 112. It will be appreciated that, at least in some embodiments, the processing system 100 includes additional modules and components not illustrated at FIG. 1, such as additional processors, memory modules, data storage components (e.g., disk drives), input/output controllers and devices, and the like.

The SMU 112 is generally configured to monitor environmental aspects of the processing system 100, such as temperature. For example, in some embodiments the processing system 100 includes one or more temperature sensors (not shown) arranged at different locations of the system, such as at different locations of a printed circuit board, at one or more integrated circuit packages including the processor 101 and the memory modules 115 and 116, and the like. Based on information provided by the temperature sensors, the SMU 112 periodically generates a temperature reading 114. As described further herein, in some embodiments the processing system 100 employs the temperature reading 114 to control one or more aspects of the processing system 100, including memory timing parameters for one or more of the memory modules 115 and 116.

The processor 101 is generally configured to execute the applications and other sets of instructions on behalf of the processing system 100. The memory modules 115 are generally configured to store data that is manipulated by the sets of instructions when executed by the processor 101. For purposes of description, it is assumed that the memory modules 115 and 116 are DRAM modules, such as dual in-line memory modules (DIMMs). In the course of executing the sets of instructions, the processor 101 generates operations, referred to herein as memory accesses. Examples of memory accesses include read operations (also referred to as a memory read) that retrieve data from a memory module and write operations (also referred to as a memory write) that write data to the memory module. To support memory accesses, the processor 101 is connected to each memory module via a set of busses. For example, the processor 101 is connected to the memory module 115 via a clock bus 117, a command bus 118, and an address/data bus 119. These busses are collectively referred to as the memory busses 117-119. It will be appreciated that while the address/data bus 119 is illustrated as a single bus, in other embodiments the processor 101 is connected to the memory module 115 via separate address and data busses. In addition, in some embodiments the memory busses 117-119 represent additional or different busses and connections to those illustrated at FIG. 1, such as one or more busses or connections to carry data strobe signals.

To execute a memory operation, the processor 101 provides specified memory signaling on the memory busses 117-119, such as a clock signal via the clock bus 117, one or more commands via the command bus 118, and a memory address and data via the address/data bus 119. In response, the memory module 115 executes the memory operation indicated by the memory signaling. For some operations (e.g., memory reads), the memory module 115 provides responsive information via the memory busses 117-119, such as providing data via the address/data bus 119. The execution of the memory operations at the memory module 115 is governed by one or more memory timing parameters that govern how quickly the memory module 115 carries out specified tasks that support the memory operations. One example of a memory timing parameter is the frequency of the clock signal provided by the processor 101 via the clock bus 117. As the frequency of the clock signal increases, the memory module 115 executes at least some memory operations, such as read and write operations, more quickly.

Other memory timing parameters govern the speed with which the memory module 115 executes associated tasks that support memory operations. For example, in some embodiments the memory module 115 includes a storage array that stores a relatively large amount of data that is accessed relatively slowly and a row buffer that stores a relatively small amount of data that is accessed relatively quickly. To increase overall access speeds, in response to a memory access to a location of the storage array, the memory module 115 loads a specified block of data, referred to as a memory page (e.g. memory page 111) into the row buffer and satisfies memory accesses targeted to the memory page from the row buffer. This allows frequent accesses to the memory page over a short amount of time to be executed relatively quickly. The speed with which the memory module 115 loads a page to the row buffer is governed by one or more memory timing parameters, such as one or more page loading parameters. Other examples of memory timing parameters include a row precharge parameter, a column-to-column delay parameter, a row-to-row delay parameter, a four-bank activation window parameter, a write recovery (WR) parameter, a read to precharge (RTP) parameter, a refresh interval (REFI) parameter, and the like.

In some embodiments, one or more of the memory timing parameters that govern operations at the memory modules 115 and 116 are adjustable. For example, in some embodiments the clock frequency of the memory clock signal provided via the clock bus 117 is adjustable by the processor 101. Other memory timing parameters are adjusted by the processor 101 sending a specified command to the memory module 115 via the command bus 118. Still other memory timing parameters are adjusted by the processor 101 changing the voltage of the memory signaling provided to the memory module 115. However, in some cases adjusting a memory timing parameter above a specified level or outside of a specified range has associated costs, such as raising the temperature of one or more components of the processing system 100, wherein such costs impact overall system performance. Further, in at least some embodiments adjusting the memory timing parameters outside of a specified range does not provide performance benefits for a given workload executing at the processor 101. Accordingly, in some embodiments the processor 101 is configured to adjust the memory timing parameters associated with the memory modules 115 and 116 based on the expected memory access behavior of a workload executing at the processor 101.

To illustrate, the processor 101 includes a processing unit 102 and a memory controller 110. The processing unit 102 includes one or more processor cores, compute units, or other processing elements generally configured to execute sets of instructions or commands based on the sets of the instructions. Thus, in some embodiments the processing unit 102 is a central processing unit (CPU) that includes one or more processor cores configured to execute threads of instructions on behalf of the processor 101. In other embodiments, the processing unit 102 is a graphics processing unit (GPU) that includes one or more compute units configured to execute vector and graphics processing operations based on commands received from a CPU. It will be appreciated that although FIG. 1 illustrates a single processing unit 102 for convenience, in other embodiments the processor 101 or the processing system 100 includes additional processing units not illustrated at FIG. 1.

The processing unit 102 executes sets of operations collectively referred to as workloads (e.g., workload 104). In different embodiments the workload 104 represents different granularities of operations. For example, in some embodiments the workload 104 represents all the operations associated with a corresponding application. In other embodiments, the application has multiple phases, with each phase corresponding to a different pattern of memory access behavior, and the workload 104 represents the operations corresponding with one of the multiple phases of the application.

The memory controller 110 is generally configured to manage the execution of memory operations executed by the processing unit 102. For example, in some embodiments the memory controller 110 manages the logical and physical (PHY) layer operations associated with the memory accesses. Thus, in some embodiments the memory controller 110 performs tasks such as buffering of memory accesses, address translation for memory accesses, generating memory signaling based on memory accesses, providing the memory signaling via the memory busses 117-119, buffering data received in response to the memory accesses, and providing the responsive data to the processing unit 102.

In addition, the memory controller 110 is configured to adjust the memory timing parameters of one or more of the memory modules 115 and 116 based on the expected memory access behavior of the workload 104, as well as based on the temperature reading 114 to ensure that the processing system 100 remains within specified thermal limits. To illustrate, the memory controller 110 includes a timing parameter control module 106 that is configured to set the timing parameters for the memory module 115 based on a set of workload profiles 107 and a thermal budget 108. The thermal budget 108 indicates an overall amount of thermal energy that is permitted at the processor 101 to ensure reliable operation. In at least some embodiments, the thermal budget 108 is generated and stored at the processor 101 during a characterization or other design or manufacturing phase of the processor 101 or the processing system 100. The timing parameter control module 106 is configured to determine, based on a comparison of the thermal budget 108 and the temperature reading 114, and amount of thermal headroom available at the processor 101.

The workload profiles 107 is a data structure that stores information indicating memory timing parameters for different workloads, and for different amounts of thermal headroom. For example, in some embodiments the workload profiles 107 represent a table similar to the following Table 1:

TABLE 1

| Workload ID | Thermal Headroom | MTP Settings |
|---|---|---|
| A | 3 degrees or less | Q |
| A | 3-5 degrees | P |
| B | 3 degrees or less | R |
| B | 3-5 degrees | S |

Table 1 includes 3 columns, a Workload ID column, a Thermal Headroom column, and a Memory Timing Parameter (MTP) Settings Column. The entries of the Workload ID column represent a workload identifier for workloads to be executed at the processing unit 102. The entries of the Thermal Headroom column indicate an amount of thermal headroom identified by the timing parameter control module 106, and the entries MTP Settings column represent memory timing parameter settings, such as clock frequencies, page loading parameters, row precharge parameters, column-to-column delay parameters, row-to-row delay parameters, four-bank activation window parameters, and the like. Thus, the MTP Settings entry for a given row indicate the memory timing parameter settings for the workload indicated in the corresponding Workload ID when the amount of thermal headroom corresponds to the headroom indicated in the corresponding Thermal Headroom entry. Thus, the first row of Table 1 indicates that, for a Workload A, with 3 degrees of thermal headroom, the memory controller 110 is to set the memory timing parameters for the memory module 115 to settings “Q”, where Q represents a set of memory timing parameter values. The second row of Table 1 indicates that, for the Workload A, with 3 degrees of thermal headroom, the memory controller 110 is to set the memory timing parameters for the memory module 115 to settings “P”, where P represents a set of memory timing parameter values different than settings Q.

In operation, the memory controller 110 1) identifies the workload executing, or to be executed, at the processing unit 102, 2) identifies the thermal headroom by comparing the temperature reading 114 to the thermal budget 108; 3) identifies the entry of the workload profiles 107 corresponding to the combination of identified workload and thermal headroom; and 4) sets the memory timing parameters for the memory module 115 to the values indicated by the identified entry of the workload profiles 107. To identify the workload, in some embodiments the memory controller 110 employs a workload identifier. For example, in some embodiments the workload corresponds to an executing application, and an operating system executing at the processor 101 provides an identifier for the executing application to the memory controller 110, which uses the identifier to determine the entries of workload profiles 107 corresponding to the executing application.

In other embodiments, the memory controller 110 is configured to identify a type of executing workload based on memory access patterns, and the workload profiles indicate the memory timing parameters for each workload type. For example, in some embodiments the processor 101 includes a set of performance counters (not shown) that record information representing one or more characteristics associated with memory accesses to the memory module 115, such as a memory traffic rate associated with the a workload (e.g., a number of memory accesses generated over a specified amount of time), a number of memory reads associated with a workload, a number of memory writes associated with a workload, a size of memory accesses associated with a workload, a spatial locality associated with a workload, a number of memory requests associated with a workload that result in a memory page hit, a number of memory requests associated with a workload that result in a memory page miss, and a number of memory requests associated with a workload that result in a memory page conflict, and the like. Based on one or more of these characteristics indicated by the performance counters, the timing parameter control module 106 identifies a type of the executing workload. The timing parameter control module 106 then determines the set of entries of the workload profiles 107 corresponding to the identified workload type and determines from the set of entries the individual entry corresponding to the amount of thermal headroom. The timing parameter control module 106 sets the memory timing parameters of the memory module 115 to the values indicated by the identified entry of the workload profiles 107.

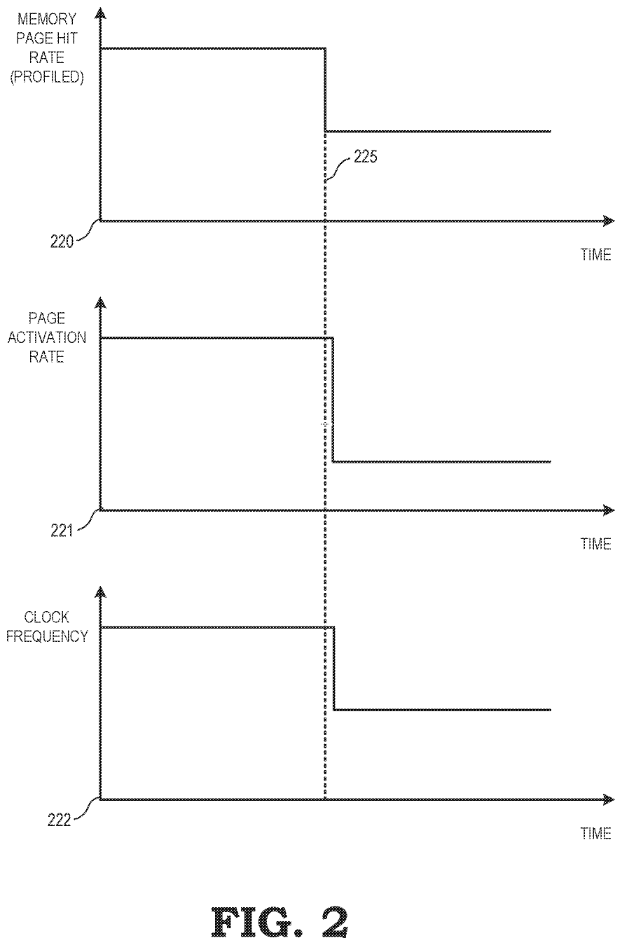

An example of the memory controller 110 adjusting memory timing parameters based on changes in memory access patterns is illustrated at FIG. 2 in accordance with some embodiments. FIG. 2 illustrates three charts 220, 221, and 222, each having an X-axis and a Y-axis, with the X-axis of each of the charts 220-222 representing time. The Y-axis of the chart indicates the memory page hit rate at the memory module 115—that is, the rate at which the memory page loaded into a row buffer of the memory module 115 is targeted by a memory access. The Y-axis of the chart 221 indicates a page latency of the memory module 115, which is a memory timing parameter governing how quickly the memory module 115 loads a memory page. The Y-axis for the chart 222 indicates a clock frequency of the clock signal provided by the memory controller 110 via the clock bus 117. It is assumed for purposes of the example of FIG. 2 that the amount of thermal headroom at the processor 101 remains constant, or within a specified range, over time.

In the depicted example, prior to a time 225, the timing parameter control module 106 has identified a relatively high memory page hit rate for the workload executing at the processing unit 102 and in response, and based on the workload profiles 107, has set the page activation latency and clock frequency to relatively high levels. At time 225, the timing parameter control module 106 determines, based on performance counters at the processor 101, that the memory page hit rate has fallen below a threshold, and therefore determines that the workload executing at the processing unit 102 has changed, either due to a change in executing applications, or due to the same application entering a different application phase. In response to the change in workload, the timing parameter control module 106 determines, based on the workload profiles 107, the memory timing parameter values for the new workload and sets the memory timing parameters for the memory module 115 to the indicated values.

In the example of FIG. 2, the workload profiles 107 indicate that, for the workload having a lower memory page hit rate, the page activation latency is to be reduced, thereby lowering the time required for the memory module 115 to load memory pages to the row buffer and improving memory access performance. In addition, the workload profiles 107 indicate that, for the workload having the lower memory page hit rate, the frequency of the memory clock signal is to be reduced, thereby conserving power and thermal headroom without impacting memory access performance, as such performance is expected to be limited by the page activation latency. The timing parameter control module 106 sets the page activation latency and memory clock frequency to the values indicated by the workload profiles 107, thereby improving memory access performance for the new workload while conserving power. Thus, in the example of FIG. 2, the processor 101 adjusts the memory timing parameters based on the executing workload, supporting improved performance without a commensurate increase in power consumption and a commensurate loss of thermal headroom.

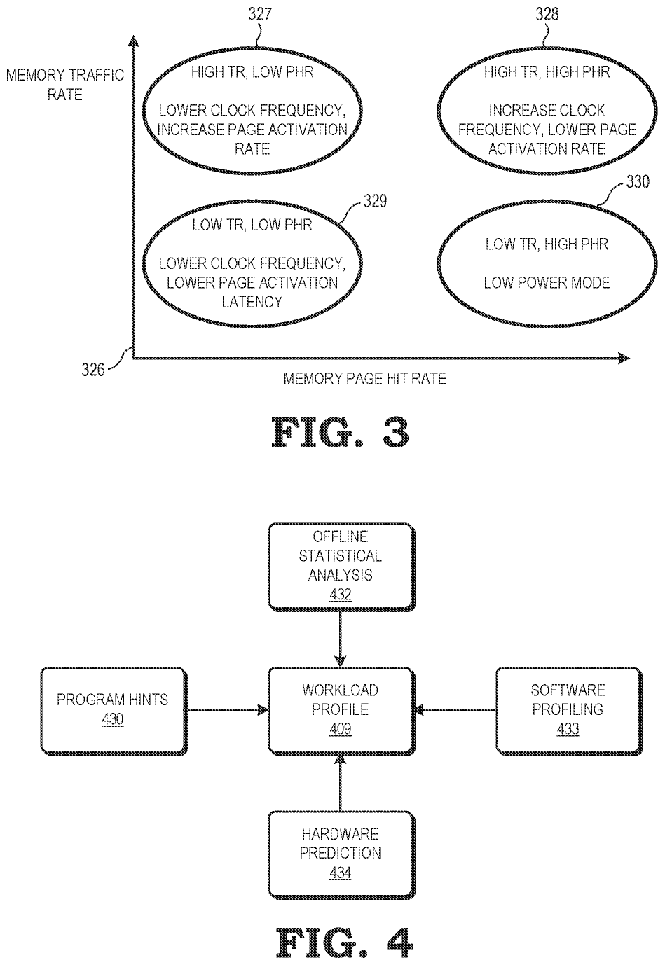

In some embodiments, the workload profiles 107 are set based on a combination of different memory access characteristics to tune the memory timing parameters based on a variety of memory access patterns. An example is illustrated at FIG. 3 in accordance with some embodiments. FIG. 3 illustrates an example of the relative values of memory timing parameters, as indicated by the workload profiles 107, based on a combination of memory traffic rate and memory page hit rate.

FIG. 3 illustrates a chart 326 having an X-axis indicating a memory page hit rate at the memory module 115 and a Y-axis indicating a memory traffic rate at the memory module 115 (e.g., the number of memory accesses provided to the memory module 115 over a specified amount of time). The chart 326 also illustrates four regions 327, 328, 329, and 330, with each region representing a different combination of memory access patterns at the memory module 115 and corresponding memory timing parameter settings.

Region 327 corresponds to a high memory traffic rate and a low memory page hit rate. Accordingly, the memory timing parameter settings for region 327 are a relatively low memory clock frequency and an increased memory page activation rate. Region 328 corresponds to a high memory traffic rate and a high memory page hit rate. The memory timing parameter settings for region 328 are an increased memory clock frequency and a lower page activation rate.

Region 329 corresponds to a low memory traffic rate and a low memory page hit rate. The memory timing parameter settings for region 329 are a relatively low memory clock frequency and a relatively lower page activation latency. Region 330 corresponds to a low memory traffic rate and a high memory page hit rate. Accordingly, the memory timing parameter settings for region 328 correspond to a low power mode, such as a lowering memory clock frequency and values for other memory timing parameters corresponding to values that reduce power consumption by the memory module 115.

In operation, the timing parameter control module 106 periodically determines, based on performance information provided by performance counters of the processor 101, the memory traffic rate and memory page hit rate, thereby determining a type of the workload executing at the processing unit 102. Based on the traffic rate and page hit rate, the timing parameter control module 106, selects the corresponding regions 327-330, and employs the workload profiles 107 to determine the memory timing parameter values corresponding to the identified region. The timing parameter control module 106 then sends the requisite commands, and adjusts the requisite voltages and clock frequencies, to set the memory timing parameters for the memory module 115 to the memory timing values indicated by the workload profiles 107.

As noted above, in different embodiments the workload profiles are generated based on one or more profiling tools, or a combination thereof. An example is illustrated at FIG. 4 in accordance with some embodiments. In the depicted example, a workload profile 409 is generated based on program hints 430, offline statistical analysis information 432, software profiling information 433, and hardware prediction information 434. The program hints 430 represent information provided by the workload itself as to the expected memory access patterns of the workload. For example, in some embodiments the program hints 430 represent an indication, inserted into an application by an application developer, that a particular phase of the application is expected to generate a high memory traffic rate, a high page hit rate, and the like, or a combination thereof.

The offline statistical analysis information 432 represents workload profile information generated via testing and analysis of the workload in a test or development environment, before the workload is executed at the processor 101. For example, in some embodiments the offline statistical analysis information 432 represents information generated during compilation of an application using statistical analysis techniques or by running a sample of the application, or portion thereof, at a test processor. In some embodiments, the offline statistical analysis information is stored in metadata of the compiled binary of the corresponding application and can include memory timing parameter information for the entire application or for smaller blocks of code within the overall application code. The processor 101 can access the stored metadata in any of a variety of ways, including by extracting the metadata during runtime(i.e., during execution of the application at the processor 101), via the use of specific application instructions that set the memory access timing parameter values, via the use of MMIO to inform the memory controller of the memory access timing parameter values for the application or application phases, or by having firmware of the processor 101 execute a control loop encoded in the metadata to extract the memory access timing parameter values.

The software profiling information 433 represents profiling information generated by software during execution of an application or application phase. For example, in some embodiments the memory access behavior is profiled at runtime using performance profiling tools. The profiled information is used as inputs to a specified model that generates memory access timing parameter values. In some embodiments the memory access parameter values are generated at a specified time granularity, while in other embodiments the memory access parameter values are generated after a fixed number of instructions. In different embodiments, the software profiling is performed by a dedicated profiling tool, by an operating system executing at the processor 101, or by the application itself, using performance monitors of the processor 101 and by calling an operating system to set the memory access parameter values for the workload profile 409. The hardware prediction information 434 represents profiling information generated by hardware of the processor 101 in similar fashion to the software profiling information 433 but using dedicated hardware to allow setting of memory access timing parameter values at a finer granularity. In some embodiments, the profiling information is generated at least in part by firmware executing at the processor 101.

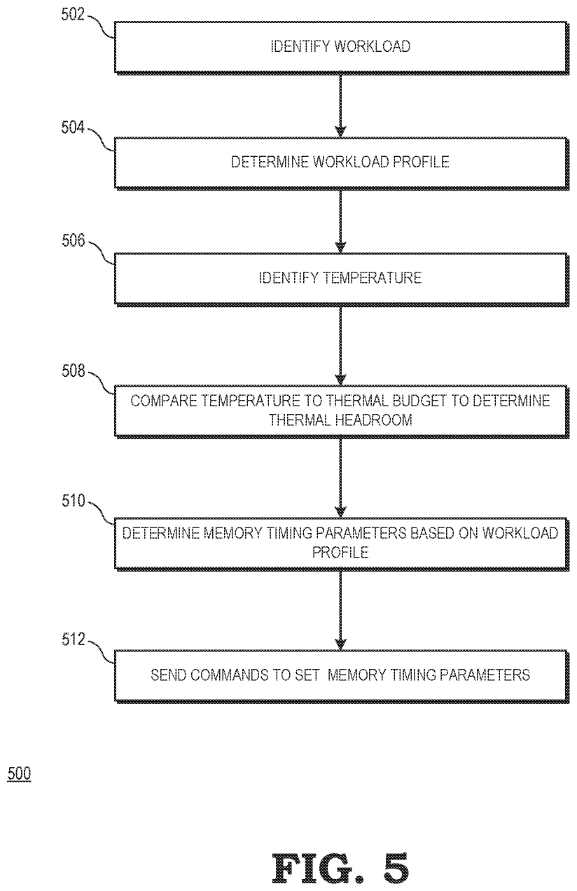

FIG. 5 illustrates a flow diagram of a method 500 of setting memory access timing parameters in accordance with some embodiments. For purposes of description, the method 500 is described with respect to an example implementation at the processing system 100 of FIG. 1. At block 502, the timing parameter control module 106 determines the workload 104 executing at the processor 101 based on a workload identifier, based on performance information indicated by one or more performance counters, and the like, or any combination thereof. At block 504, the timing parameter control module 106 determines the workload profile corresponding to the identified workload.

At block 506, the timing parameter control module 106 identifies a temperature of the processor 101 by receiving the temperature reading 114 from the SMU 112. At block 508, the timing parameter control module 106 compares the temperature to the thermal budget 108 to determine an amount of available thermal headroom for the processor 101. At block 510, the timing parameter control module employs the workload profile identified at block 504 to identify the memory timing parameter values for the amount of thermal headroom identified at block 508. At block 512, the memory controller 110 sets the memory timing parameters for the memory module 115 to the values identified at block 510.

In some embodiments, certain aspects of the techniques described above may implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
setting a first timing parameter for a first memory module based on a first workload profile, the first workload profile indicating a memory access pattern to be executed at a processing unit.

2. The method of claim 1, further comprising:
setting the first timing parameter further based on a thermal budget for the processing unit.

3. The method of claim 2, further comprising:
setting the first timing parameter further based on a detected temperature at the processing unit.

4. The method of claim 1, wherein the first workload profile indicates at least one of a memory traffic rate associated with the first workload, a number of memory reads associated with the first workload, a number of memory writes associated with the first workload, a size of memory accesses associated with the first workload, and a spatial locality associated with the first workload.

5. The method of claim 1, wherein the first workload profile indicates at least one of a number of memory requests associated with the first workload that result in a memory page hit, a number of memory requests associated with the first workload that result in a memory page miss, and a number of memory requests associated with the first workload that result in a memory page conflict.

6. The method of claim 1, wherein the first timing parameter comprises a clock frequency of a memory clock signal.

7. The method of claim 1, wherein the first timing parameter comprises at least one of a page loading parameter, a row precharge parameter, a column-to-column delay parameter, a row-to-row delay parameter, a four-bank activation window parameter, a write recovery (WR) parameter, a read to precharge (RTP) parameter, and a refresh interval (REFI) parameter.

8. The method of claim 1, wherein the first workload profile is based on an offline statistical analysis of memory accesses associated with the first workload.

9. The method of claim 1, wherein the first workload profile comprises is based on a runtime profile of memory accesses associated with the first workload.

10. The method of claim 1, wherein the first workload profile is based on patterns of previous memory accesses associated with the first workload.

11. The method of claim 1, further comprising:
setting the first timing parameter for the first memory module based on a second workload profile for a second workload to be executed at the processing unit.

12. The method of claim 1, further comprising:
setting a second timing parameter for the first memory module based on the first workload profile.

13. A method, comprising:
setting a timing parameter for a memory module based on a workload profile associated with a workload executing at a processing unit and based upon a thermal budget associated with the processing unit.

14. A processor, comprising:
a processing unit to execute a workload; and
a memory controller to:
set a first timing parameter for a memory module based on a workload profile indicating a memory access pattern of the workload.

15. The processor of claim 14, wherein the memory controller is to:
set the timing parameter further based on a thermal budget for the processing unit.

16. The processor of claim 15, wherein the memory controller is to:
set the timing parameter further based on a detected temperature at the processing unit.

17. The processor of claim 14, wherein the workload profile is based on at least one of a memory traffic rate associated with the workload, a number of memory reads associated with the workload, a number of memory writes associated with the workload, a size of memory accesses associated with the workload, and a spatial locality associated with the workload.

18. The processor of claim 14, wherein the workload profile is based on at least one of a number of memory requests associated with the workload that result in a memory page hit, a number of memory requests associated with the workload that result in a memory page miss, and a number of memory requests associated with the workload that result in a memory page conflict.

19. The processor of claim 14, wherein the first timing parameter comprises a clock frequency of a memory clock signal.

20. The processor of claim 14, wherein the first timing parameter comprises at least one of a page loading parameter, a row precharge parameter, a column-to-column delay parameter, a row-to-row delay parameter, a four-bank activation window parameter, a write recovery (WR) parameter, a read to precharge (RTP) parameter, and a refresh interval (REFI) parameter.
